(19) United States
(12) Patent Application Publication
(10) Pub. No.: US 2014/0022000 A1
(43) Pub. Date: Jan. 23, 2014

(54) Switching Circuit with a Base Discharge Switch

(71) Applicant: International Rectifier Corporation, El Segundo, CA (US)

(72) Inventor: Thomas J. Ribarich, Laguna Beach, CA (US)

(21) Appl. No.: 13/922,624

(22) Filed: Jun. 20, 2013

Related U.S. Application Data
(60) Provisional application No. 61/674,654, filed on Jul. 23, 2012.

(51) Int. Cl. H03K 17/0412

(52) U.S. Cl. CPC H03K 17/04126
USPC 327/377

(57) ABSTRACT

According to an exemplary implementation, a switching circuit includes a bipolar junction transistor, a base current supply configured to turn-on the bipolar junction transistor, and a base discharge switch configured to selectively draw current away from a base of the bipolar junction transistor so as to turn-off the bipolar junction transistor. The base discharge switch can further be configured to selectively prevent the base current supply from providing current to the base of the bipolar junction transistor. The base discharge switch may be coupled across the base of the bipolar junction transistor and an emitter of the bipolar junction transistor. The base discharge switch can further be configured to selectively cause the base of the bipolar junction transistor to have a base voltage substantially lower than an emitter voltage of the bipolar junction transistor.

### BACKGROUND

The present application claims the benefit of and priority to a pending provisional application entitled “Bipolar Junction Transistor Switching Control Circuit,” Ser. No. 61/674,654 filed on Jul, 23, 2012. The disclosure in this pending provisional application is hereby incorporated fully by reference into the present application.

In driving a bipolar junction transistor (BJT), a dedicated transformer may supply current to a base of the BJT to turn-on and turn-off the BJT. Total base current for the BJT to turn-on and turn-off can be on a primary winding of the dedicated transformer and may be applied directly to the base of the BJT. Circuitry can be utilized to carefully control the total base current on the primary winding to reliably achieve a switching frequency of the BJT. Otherwise, the switching frequency may experience instability as current supplied from the dedicated transformer can vary.

Also in driving a BJT, a resonant tank may be utilized to provide current to the base of the BJT to turn-on and turn-off the BJT. The switching frequency of the BJT may be synched to a resonance frequency of the resonant tank. The resonance frequency may be dependent on load resistance and a bus voltage, which can vary. Thus, the switching frequency of the BJT may vary unless the load resistance and the bus voltage are made stable.

### SUMMARY

The present disclosure is directed to a switching circuit with a base discharge switch, substantially as shown in and/or described in connection with at least one of the figures, and as set forth more completely in the claims.

### BRIEF DESCRIPTION OF THE DRAWINGS

FIG. 1 presents an exemplary switching circuit, in accordance with implementations of the present disclosure.

FIG. 2A presents an exemplary switching circuit after turn-on of a bipolar junction transistor, in accordance with implementations of the present disclosure.

FIG. 2B presents an exemplary switching circuit after turn-off of a bipolar junction transistor, in accordance with implementations of the present disclosure.

FIG. 3 presents waveforms for an exemplary switching circuit, in accordance with implementations of the present disclosure.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

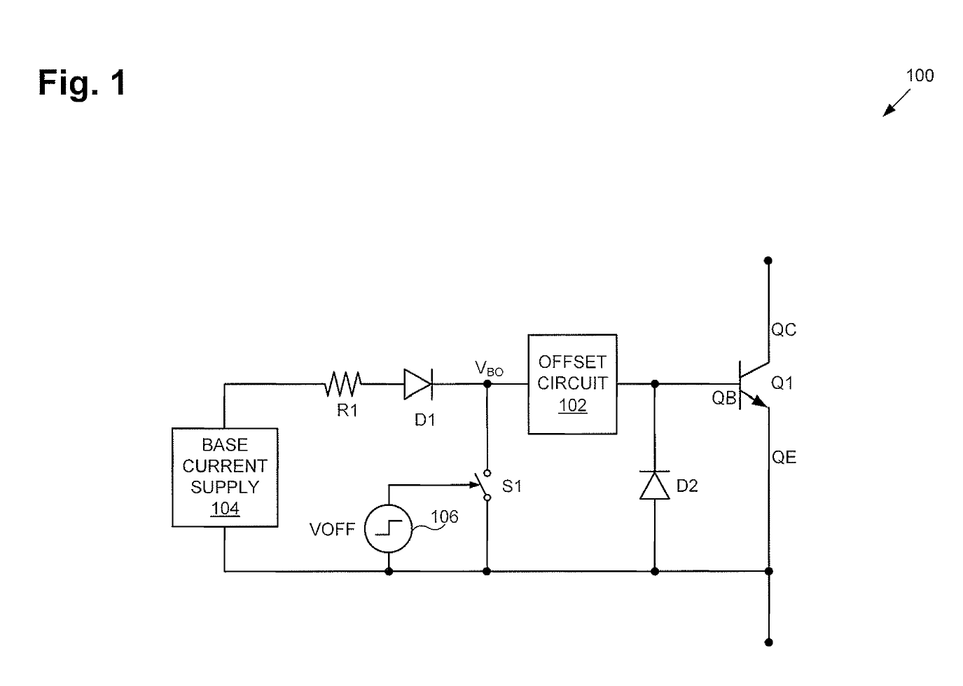

FIG. 1 presents switching circuit 100, in accordance with implementations of the present disclosure. Switching circuit 100 includes offset circuit 102, base current supply 104, pulse width modulator 106, bipolar junction transistor (BJT) Q1, base discharge switch S1, limiting resistor R1, blocking diode D1, and protection diode D2.

BJT Q1 includes base QB, emitter QE, and collector QC. In the present implementation, BJT Q1 is an NPN BJT, but in other implementations BJT Q1 is a PNP BJT. BJT Q1 is configured to switch power from a bus voltage (not shown in FIG. 1).

The bus voltage can be connected to collector QC and a lower voltage (e.g. ground) can be coupled to emitter QE. By switching BJT Q1, switching circuit 100 can power a load that may be coupled to emitter QE.

Switching circuit 100 can have various topologies, which can vary from what is shown in FIG. 1. For example, while not specifically shown, BJT Q1 may optionally be included in a larger switching circuit, such as a half-bridge switching circuit. BJT Q1 can be a low side or a high side switch of the half-bridge switching circuit. Furthermore, certain implementations may not include certain features shown, such as any combination of limiting resistor R1, blocking diode D1, protection diode D2, and offset circuit 102.

In switching circuit 100, base current supply 104 is configured to turn-on BJT Q1. More particularly, base current supply 104 is configured to provide current to base QB of BJT Q1 so as to turn-on BJT Q1. As shown in FIG. 1, base current supply 104 is coupled across base QB and emitter QE of BJT Q1. Base current supply 104 can be a voltage source or a current source. For example, base current supply 104 may be an alternating current (AC) voltage or current source. However, base current supply 104 may also be a direct current (DC) voltage or current source. Thus, base current supply 104 may provide AC or DC current to base QB of BJT Q1.

Also in switching circuit 100, limiting resistor R1 is configured to limit current provided by base current supply 104. Blocking diode D1 is configured to block negative current from flowing into base current supply 104. A series configuration of limiting resistor R1 and blocking diode D1 are coupled between base current supply 104 and offset circuit 102.

Offset circuit 102 is optionally coupled between base QB of bipolar junction transistor Q1 and base current supply 104. For example, FIG. 1 shows offset circuit 102 coupled to blocking diode D1 and base discharge switch S1 at one end and base QB and protection diode D2 at another end. Utilizing such a configuration, base current supply 104 can be configured to power offset circuit 102 that generates offset voltage V_{BO} as shown in FIG. 1. However in other implementations, power offset circuit 102 may be powered utilizing other means and may not be coupled between base QB of bipolar junction transistor Q1 and base current supply 104.

Offset circuit 102 is configured to provide offset voltage V_{BO} to base QB of BJT Q1 so as to turn-off BJT Q1. In doing so, base QB of BJT Q1 can be made to have a base voltage substantially lower than an emitter voltage of BJT Q1. For example, offset voltage V_{BO} can impress a negative voltage on base QB of BJT Q1. By applying offset voltage V_{BO} to base QB of BIT Q1, BJT Q1 can be made to turn-off rapidly. More particularly, BJT Q1 may other wise take longer to turn-off due to charge stored in base QB. By utilizing offset voltage V_{BO}, BJT Q1 can be used in higher frequency applications than may otherwise be practical. For example, without offset voltage V_{BO}, the switching frequency of BJT Q1 may be, for example, as much as approximately 100 kHz. With the offset voltage V_{BO}, the switching frequency of BJT Q1 may be, for example, as much as approximately 300 kHz. However, offset circuit 102 and offset voltage V_{BO} are not included in every implementation of the present disclosure.

Base discharge switch S1 is coupled across base QB of BJT Q1 and emitter QE of BIT Q1. Base discharge switch S1 can be many different types of switches. For example, base discharge switch S1 can include a transistor, such as an NPN or PNP transistor. Examples of base discharge switch S1 include a metal-oxide field-effect transistor (MOSFET) or a BJT. Base discharge switch S1 can be a low voltage switch and can thereby be provided at a low cost. Various implementations of base discharge switch S1 are not limited to using a single transistor as shown merely as an example in the drawings of the present application. Base discharge switch S1 can take many forms, and can include more than one transistor and might include other circuit elements as well, so as long as base discharge switch S1 can perform the switching functions discussed in the present application.

Base discharge switch S1 is configured to selectively draw current away from base QB of BJT Q1 so as to turn-off BJT Q1. This may be accomplished, for example, by turning-on base discharge switch S1 so as to provide a low resistance path for the current. The current may be drawn away from base QB of BJT Q1 through, for example, offset circuit 102. Base discharge switch S1 is further configured to selectively prevent base current supply 104 from providing current to base QB of BJT Q1. This may also be accomplished, for example, by turning-on base discharge switch S1 so as to provide a low resistance path for current from base current supply 104. Thus, control of BJT Q1 may not be as susceptible to variation in base current supply 104. As such, circuitry may not be required to carefully control switching of base current supply 104. Furthermore, switching of BJT Q1 can remain substantially stable and controllable even where load resistance and/or the bus voltage varies.

Pulse width modulator 106 can be utilized to control base discharge switch S1 using control signal VOFF. Thus, base discharge switch S1 can be controlled by a pulse width modulated signal corresponding to control signal VOFF in FIG. 1. It is noted that base discharge switch S1 can be controlled utilizing other means and pulse width modulator 106 need not be connected to emitter QE as shown in FIG. 1.

Base discharge switch S1 is also configured to selectively apply offset voltage V_{BO} to base QB of BJT Q1 so as to cause base QB of BJT Q1 to have a base voltage substantially lower than an emitter voltage of BJT Q1. This may be accomplished, for example, by turning-on base discharge switch S1. Furthermore, offset voltage V_{BO} can be selectively applied to base QB of BJT Q1 so as to turn-off BJT Q1. By doing so, base discharge switch S1 can selectively draw current away from base QB of BJT Q1 more rapidly than may otherwise be possible. In this way, BJT Q1 can be made to turn-off rapidly.

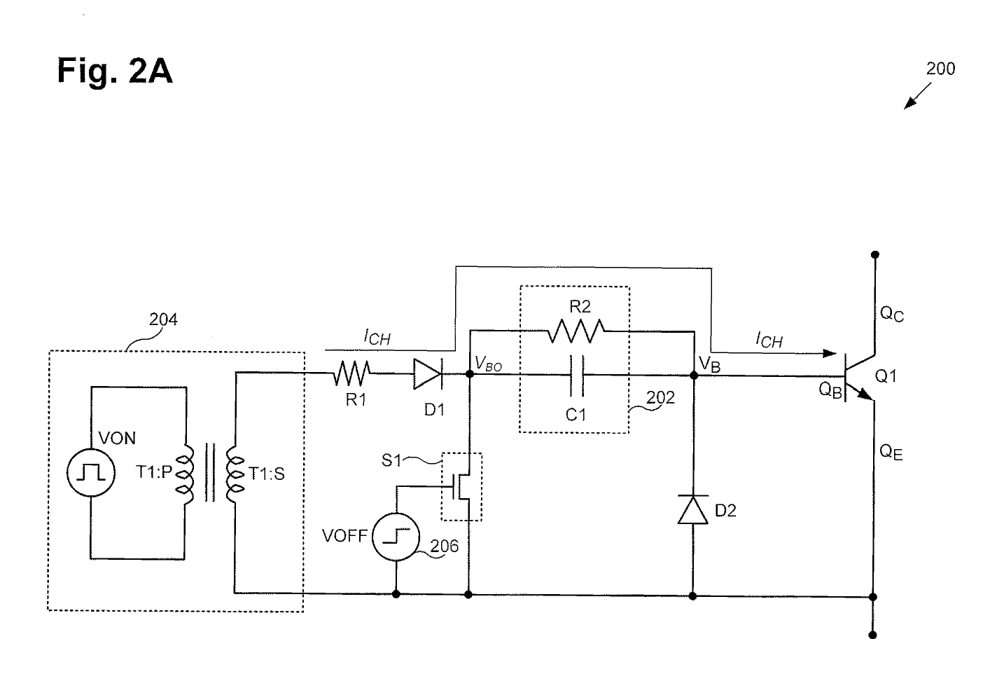

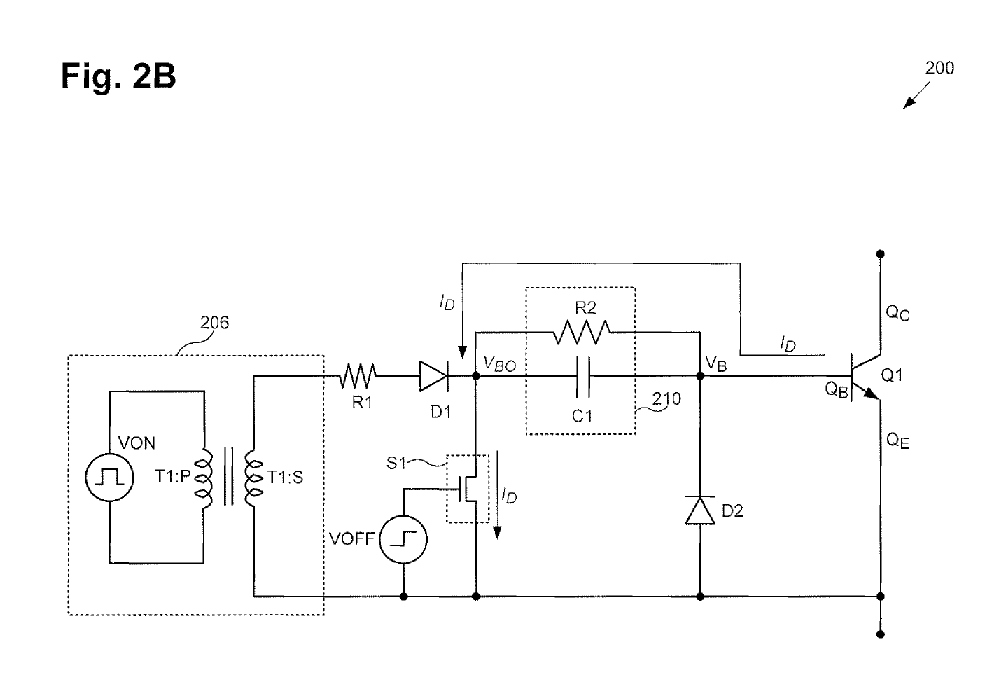

Referring to FIGS. 2A and 2B, FIG. 2A presents switching circuit 200 after turn-on of bipolar junction transistor (BJT) Q1, in accordance with implementations of the present disclosure. FIG. 2B presents switching circuit 200 after turn-off of BJT Q1, in accordance with implementations of the present disclosure. Switching circuit 200 corresponds to switching circuit 100 in FIG. 1. Switching circuit 200 includes offset circuit 202, base current supply 204, pulse width modulator 206, BJT Q1, base discharge switch S1, limiting resistor R1, blocking diode D1, and protection diode D2 corresponding respectively to offset circuit 102, base current supply 104, pulse width modulator 106, BJT Q1, base discharge switch S1 limiting resistor R1, blocking diode D1, and protection diode D2 in FIG. 1.

In switching circuit 200, base current supply 204 is an AC voltage source. More particularly, base current supply 204 includes a multi-winding transformer having primary winding T1:P and secondary winding T1:S (also referred to more generally as an inductor winding). Switching circuit 200 does not require a dedicated multi-winding transformer. Furthermore, the inductor winding may not be part of a multi-winding transformer, which can save on cost. Primary winding T1:P is configured to receive control signal VON. Control signal VON is configured to control turn-on of BJT Q1.

Also in switching circuit 200, offset circuit 202 includes a resistor-capacitor (RC) filter having resistor R2 and capacitor C1. Resistor R2 and capacitor C1 are coupled between base QB of BJT Q1 and base discharge switch S1. As such, base discharge switch S1 can draw current away from base QB through offset circuit 202. Furthermore, resistor R2 and capacitor C1 are coupled between base QB of BJT Q1 and base current supply 204. As such, base current supply 204 can power offset circuit 202 and can further provide current to base QB through offset circuit 202.

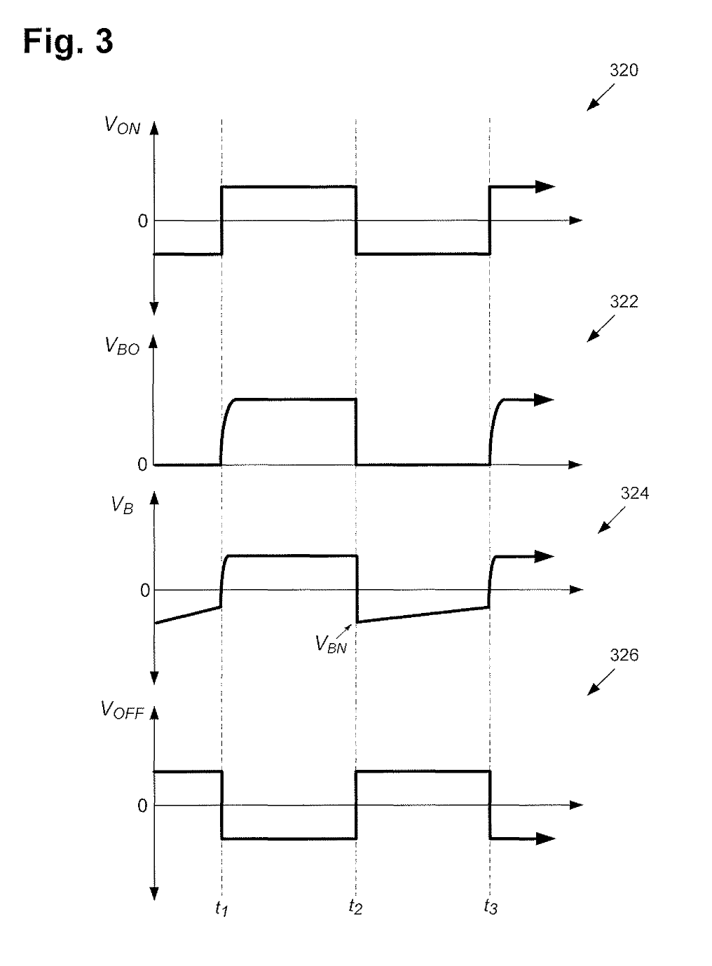

Referring to FIG. 3 with FIGS. 2A and 2B, FIG. 3 presents waveforms 320, 322, 324, and 326 of switching circuit 200. At time t1, control signal VOFF goes low as shown in waveform 326 to turn-off base discharge switch S1. As control signal VON is high between times t1 and t2, base current supply 204 can provide charge current I_{CH} to base QB of BJT Q1 so as to turn-on BJT Q1. Waveform 324 shows base voltage V_{B} is charged and BJT Q1 is thereby turned-on. Furthermore, in the present implementation, base current supply 204 can power offset circuit 202 that generates offset voltage V_{BO}. Thus, between times t1 and t2 offset voltage V_{BO} is generated by offset circuit 202 as shown in waveform 322 responsive to control signals VON and VOFF.

At time t2, control signal VOFF goes high as shown by waveform 326 to turn-on base discharge switch S1. As such, base discharge switch S1 draws discharge current I_{D} away from base QB of BJT Q1 so as to turn-off BJT Q1. As illustrated by waveform 324, base voltage VB is discharged at time t2 and BJT Q1 is thereby turned-off. Furthermore, in the present implementation, at time t2, base discharge switch S1 optionally applies offset voltage V_{BO} to base QB of BJT Q1 so as to cause base QB of BJT Q1 transistor to have base voltage V_{B} be substantially lower than an emitter voltage of BJT Q1. Thus, waveform 326 shows that offset voltage V₈₀ impresses negative voltage V_{BN} (e.g. −1 volts) on base QB of BJT Q1. As such, base QB of BJT Q1 is rapidly discharged in some implementations.

As control signal VON is low between times t2 and t3, base current supply 204 does not provide charge current I_{CH} to base QB of BJT Q1. As such, base current supply 204 cannot turn-on BIT Q1 between times t2 and t3. If control signal VON were not carefully controlled, control signal VON could be high in waveform 320 at least partially between times t2 and t3. However, in FIG. 2B, base discharge switch S1 is preventing base current supply 204 from providing charge current I_{CH} to base QB of BJT Q1. As such, base current supply 204 cannot turn-on BIT Q1 between times t2 and t3 even where control signal VON in high.

Thus, base discharge switch S1 controls turn-off of BJT Q1 and thereby can stably control switching of switching circuit 200. Furthermore, while it may be preferred that charge current is AC current in some implementations, charge current can also be DC current (e.g. substantially constant DC current) while maintaining stable switching of switching circuit 200. Also, by including base discharge switch S1, the duty cycle and/or switching frequency of BJT Q1 can be controlled more robustly than may otherwise be practical through control of control signal VOFF. For example, control signal VOFF may be generated based on various conditions, such as feedback from a load.

Thus, as described above with respect to FIGS. 1, 2A, 2B, and 3, in accordance with various implementations of the present disclosure, a switching circuit includes a base discharge switch configured to turn-off a bipolar junction transistor. The base discharge switch can thereby allow for stable control of the switching circuit. As such, the control can remain stable without careful control of a base current supply and throughout variations in load resistance and/or a bus voltage. Furthermore, the base discharge switch may selectively apply an offset voltage to the base of the bipolar junction transistor so as to cause the base of the bipolar junction transistor to have a base voltage substantially lower than an emitter voltage of the bipolar junction transistor. Thus, the bipolar junction transistor may turn-off rapidly allowing for the switching circuit to achieve a higher switching frequency.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. A switching circuit comprising:
a bipolar junction transistor;
a base current supply configured to turn-on said bipolar junction transistor;
a base discharge switch configured to selectively draw current away from a base of said bipolar junction transistor so as to turn-off said bipolar junction transistor.

2. The switching circuit of claim 1, wherein said base discharge switch is further configured to selectively prevent said base current supply from providing current to said base of said bipolar junction transistor.

3. The switching circuit of claim 1, wherein said base discharge switch is further configured to selectively cause said base of said bipolar junction transistor to have a base voltage substantially lower than an emitter voltage of said bipolar junction transistor.

4. The switching circuit of claim I, wherein said base discharge switch is coupled across said base of said bipolar junction transistor and an emitter of said bipolar junction transistor.

5. The switching circuit of claim 1 comprising an offset generator configured to provide an offset voltage to said base of said bipolar junction transistor so as to turn-off said bipolar junction transistor.

6. The switching circuit of claim 1 comprising an offset generator coupled between said base of said bipolar, junction transistor and said base discharge switch.

7. The switching circuit of claim 1 comprising a capacitor coupled between said base of said bipolar junction transistor and said base discharge switch.

8. The switching circuit of claim I wherein said base discharge switch is controlled by a pulse width modulated signal.

9. The switching circuit of claim 1, wherein said base current supply is coupled across said base and an emitter of said bipolar junction transistor.

10. The switching circuit of claim 1, wherein said base current supply comprises an alternating current (AC) voltage source.

11. The switching circuit of claim 1, wherein said base current supply comprises an inductor winding.

12. A switching circuit comprising:
a bipolar junction transistor;
a base current supply configured to turn-on said bipolar junction transistor;
a base discharge switch configured to selectively apply an offset voltage to a base of said bipolar junction transistor so as to cause said base of said bipolar junction transistor to have a base voltage substantially lower than an emitter voltage of said bipolar junction transistor.

13. The switching circuit of claim 12, wherein said offset voltage is selectively applied to said base of said bipolar junction transistor so as to turn-off said bipolar junction transistor.

14. The switching circuit of claim 12, wherein said base discharge switch is further configured to selectively draw current away from said base of said bipolar junction transistor so as to turn-off said bipolar junction transistor.

15. The switching circuit of claim 12, wherein said base discharge switch is further configured to selectively prevent said base current supply from providing current to said base of said bipolar junction transistor.

16. The switching circuit of claim 12, wherein said base current supply is configured to power an offset circuit that generates said offset voltage.

17. The switching circuit of claim 12, wherein said base discharge switch is coupled across said base of said bipolar junction transistor and said emitter of said bipolar junction transistor.

18. The switching circuit of claim 12, wherein said offset voltage is generated by a resistor-capacitor (RC) filter.

19. The switching circuit of claim 12, wherein said offset voltage is generated by an offset circuit coupled between said base of said bipolar junction transistor and said base current supply.

20. The switching circuit of claim 12, wherein said offset voltage impresses a negative voltage on said base of said bipolar junction transistor.
